(19) United States
(12) Patent Application Publication
(10) Pub. No.: US 2011/0012136 A1
(43) Pub. Date: Jan. 20, 2011

(54) DISPLAY APPARATUS

(75) Inventor: Masakuni Yamamoto, Yamato-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/667,189

(22) PCT Filed: Aug. 13, 2008
(86) PCT No.: PCT/JP2008/064768

§ 371 Date: Dec. 29, 2009

(30) Foreign Application Priority Data
Aug. 29, 2007 (JP) 2007-221980

(51) Int. Cl. H01L 51/52

(52) U.S. Cl. 257/88; 257/E51.018

(57) ABSTRACT

Provided is a display apparatus whose light extraction efficiency is not reduced even when a film thickness error of an image display device is caused. The display apparatus includes a plurality of image display devices. Each of the image display devices includes at least: a stack (3) associated with light emission and including a plurality of layers; a pair of electrodes (first transparent electrode 2, second transparent electrode 4) disposed sandwiching the stack (3); a transparent substrate (1) disposed on the one electrode (first transparent electrode 2) side; and an optical filter (circularly polarizing filter 5) and a reflective layer (sealing layer 6) formed on the other electrode (second transparent electrode 4) side in the mentioned order from the other electrode side.

### TECHNICAL FIELD

The present invention relates to a display apparatus, and more particularly, to a display apparatus including an optical filter for suppressing an interference effect of emission light.

### BACKGROUND ART

The cathode ray tube (CRT) in which electrons from an electron gun are allowed to collide with a phosphor on a screen to emit light from the phosphor with a collision energy is excellent in display quality and cost and have therefore been used for a long period of time as a display apparatus for a television receiver, a personal computer or the like.

In recent years, instead of the CRT which is heavy and bulky, a flat panel display (FPD) which is advantageous in terms of space saving convenience and portability have been under research and development and put into commercial production. Examples of the FPD include a non-emission type liquid crystal display, a self-emission type plasma display (PD), a field emission display (FED), and an organic electroluminescence (EL) display.

Of these display apparatuses, there is included a display apparatus which has a circularly polarizing filter provided on a surface thereof in order to prevent image quality degradation due to ambient light such as room light or sunlight entering a room.

A disclosed example of such a display apparatus is an organic EL display which has a circularly polarizing filter provided on a front surface thereof to remove ambient light (see Japanese Patent Application Laid-Open No. H07-142170).

Meanwhile, in order to increase the display screen size of the organic EL display, a coated display using a polymer material has been under development. FIG. 6 is a schematic diagram illustrating a structure of a conventional image display device of a coated organic EL display.

In FIG. 6, the image display device includes a glass substrate 23, a transparent electrode 24, a stack 25 associated with light emission, a metal electrode 26, and a sealing film 27. An optical filter 22 is provided on a surface of the glass substrate 23. As an example of the optical filter 22, there can be included a circularly polarizing filter.

The behavior of light emitted in the stack 25 associated with light emission and the behavior of ambient light incident on the image display device from the outside in the image display device having the structure described above is described.

First, the light emitted in the stack 25 associated with light emission is described. In FIG. 6 (left side), it is assumed that a star indicated by reference numeral 28 is a light emission point. Light emitted from the organic EL image display device can be handled as spontaneous emission light from dipoles which are disposed and oriented at random and may be considered as light from an assembly of point light sources which emit light at the same intensity in all directions. A large number of such point light sources are arranged in the vicinity of a plane determined based on a carrier balance between electrons and holes in the stack 25 associated with light emission.

With respect to the coherence length of spontaneous emission light, it can be considered that lights emitted from different point light sources do not interfere with each other. Therefore, only interference of light emitted from a single point light source needs to be taken into account and the coherence length thereof is approximately equal to the wavelength thereof or several ten times the wavelength, that is, several μm. Thus, the light emission point 28 is assumed as a typical point of a light emission plane and the influence of interference of light emitted therefrom is considered.

Of the lights emitted from the light emission point 28 in all directions, the lights extracted to the outside, which are other than lights removed by the influence of absorption or total reflection, are the following two lights. That is, there are a light which is emitted from the light emission point 28 and exits as such toward the glass substrate 23 and a light which is emitted from the light emission point 28, travels toward the metal electrode 26 and is reflected by the surface of the metal electrode 26 to travel toward the glass substrate 23.

The two lights interfere with each other at a point indicated by reference numeral 29 in FIG. 6, that is, at an interface between the stack 25 associated with light emission and the transparent electrode 24 or the like. FIG. 7 illustrates an example of results obtained by calculation on a relative amount of light extracted to the outside by the interference. In FIG. 7, the abscissa indicates an optical distance between the light emission point 28 and the surface of the metal electrode 26, which is expressed by a light emission wavelength λ in the stack 25 associated with light emission. Here, when a light emission wavelength in vacuum is expressed by λ₀ and the light emission wavelength in the stack 25 associated with light emission at a refractive index n is expressed by λ, there is the relation of λ₀=nλ. The ordinate of FIG. 7 indicates a relative light amount.

As is seen from FIG. 7, when the optical distance between the light emission point 28 and the surface of the metal electrode 26 is λ/4, the two lights strengthen each other. Therefore, the thickness of each image display device is designed so as to be suitable value based on each of the wavelengths of three primary colors of R, G, and B.

The behavior of the ambient light is described with reference to FIG. 6 (right side). A light incident from the outside transmits through the respective layers via the circularly polarizing filter 22 and is reflected by the surface of the metal electrode 26, then transmits through the respective layers again, and travels to the outside via the circularly polarizing filter 22. At this time, due to the function of the circularly polarizing filter 22 and the metal electrode 26 which serves as a reflective layer, most of the ambient light is not reflected. The function is described with reference to FIG. 8.

In FIG. 8, the circularly polarizing filter is constituted of a polarizer 32 and a quarter wavelength plate 33. A reflective layer 34 of FIG. 8 corresponds to the surface of the metal electrode 26 of FIG. 6. The polarizer 32 has a transmission axis of linearly polarized light in the x-axis direction. When non-polarized ambient light 35 transmits through the polarizer 32, the ambient light becomes linearly polarized light 36 of the x-axis direction. The quarter wavelength plate 33 has a transmission axis aligned at 45° which is a half of the angle 90° formed between the x-axis and the y-axis. When the linearly polarized light 36 transmits through the quarter wavelength plate 33, the linearly polarized light is converted into circularly polarized light 37.

The circularly polarized light 37 is reflected by the reflective layer 34 as circularly polarized light 38 of the opposite rotation. For convenience of description, this reflected light is illustrated together with the incident light on the right side of FIG. 8. After the reflection, the circularly polarized light 38 of the opposite rotation transmits through the quarter wavelength plate 33 again to be converted into linearly polarized light 39 whose polarization direction is perpendicular to the polarization direction of the linearly polarized light 36. The polarizer 32 absorbs linearly polarized light of the y-axis direction, so that the linearly polarized light 39 is absorbed by the polarizer 32, whereby light 40 reflected to the outside is reduced according to an extinction ratio of the polarizer 32.

As described above, by the function of the circularly polarizing filter serving as the optical filter and the reflective layer, most of the ambient light is removed. However, there is a problem that because of the influence of the polarizer 32 of the circularly polarizing filter, approximately one half of the amount of light emitted in the stack associated with light emission is also absorbed.

Further, as other conventional techniques, there have been disclosed a technique of disposing a light absorbing layer outside a transparent electrode on a side opposite to a light extraction electrode side (see Japanese Patent Application Laid-Open No. 2003-017264) and a technique of disposing a layer for preventing reflection by utilizing interference (see WO 2004/044998).

When an image display device of an organic EL display is to be produced, the film thickness of the device is designed so as to be an optimal value in terms of an interference effect such as shown in FIG. 7. However, there has been a problem that as is seen from FIG. 7, when the image display device is produced with the film thickness being deviated from the optimal value, the amount of light extracted to the outside is significantly reduced. In particular, when image display devices are produced by coating so as to provide a large display screen, thickness errors are liable to occur, whereby the amount of light extracted utilizing interference will vary depending on the location on the screen.

### DISCLOSURE OF THE INVENTION

The present invention has been accomplished in view of the circumstances described above, and it is, therefore, an object of the present invention to provide a display apparatus whose light extraction efficiency is not reduced even when a film thickness error of an image display device is caused.

In order to achieve the object described above, the display apparatus according to the present invention has the following features. That is, the display apparatus according to the present invention includes a plurality of image display devices. Each of the image display devices includes at least: a stack which is associated with light emission and includes a plurality of layers; a pair of transparent electrodes disposed sandwiching the stack; and an optical filter having a function of a circularly polarizing filter and a reflective layer that are formed on a side of one of the transparent electrodes which is opposite to the stack side, in the mentioned order from the one transparent electrode side.

According to the display apparatus of the present invention, even when a film thickness varies at the time of producing image display devices, there is no significant variation in the light extraction efficiency. Therefore, a display apparatus whose light extraction efficiency is not reduced can be realized.

Further features of the present invention will become apparent from the following description of exemplary embodiments with reference to the attached drawings.

### BRIEF DESCRIPTION OF THE DRAWINGS

FIG. 1 is a schematic diagram illustrating a structure of an image display device used for a display apparatus according to an embodiment of the present invention.

FIG. 2 is a flow chart illustrating a procedure for producing an image display device of a display apparatus according to an embodiment of the present invention.

FIG. 3 is a schematic diagram illustrating a structure of an image display device used for a display apparatus according to another embodiment of the present invention.

FIG. 4 is a schematic diagram illustrating a structure of an image display device used for a display apparatus according to still another embodiment of the present invention.

FIG. 5 is a block diagram illustrating a display apparatus according to an embodiment of the present invention.

FIG. 6 is a schematic diagram illustrating a structure of a typical image display device for a conventional coated organic EL display.

FIG. 7 is an explanatory diagram illustrating a variation in the amount of light emission due to a change in film thickness.

FIG. 8 is an explanatory diagram illustrating an action of a circularly polarizing filter.

### BEST MODE FOR CARRYING OUT THE INVENTION

Hereinafter, a best mode for carrying out the display apparatus according to the present invention is described in detail with reference to the attached drawings.

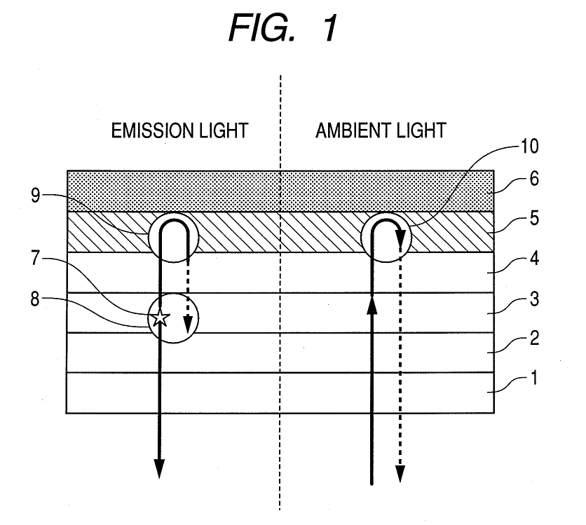

FIG. 1 is a schematic diagram illustrating a structure of an image display device used for a display apparatus according to an embodiment of the present invention.

In FIG. 1, a transparent substrate 1 is made of a material such as glass or plastic. In this embodiment, a glass substrate is used. Further, a first transparent electrode 2 is made of ITO, ZnO or the like. A stack 3 is associated with light emission and includes at least one layer which includes an organic EL material. For example, the stack 3 is constituted of a hole injection layer made of PEDOT-PSS, an emission layer made of a coatable organic EL material of a high molecular weight or a middle molecular weight, and an electron injection layer made of Cs₂CO₃. Of course, the stack 3 which is associated with light emission and includes the emission layer made of the organic EL light-emitting material is not limited to the above.

Moreover, a second transparent electrode 4 is made of ITO, ZnO or the like and serves, together with the first transparent electrode 2, as a pair of electrodes. The second transparent electrode 4 may be made of the same material as the first transparent electrode 2 or different in material therefrom. A circularly polarizing filter 5 serves as an optical filter. A sealing layer 6 serves as a reflective layer. In this embodiment, description is made by taking the case where the circularly polarizing filter 5 is used as the optical filter. However, the optical filter may further have other functions.

In FIG. 1 (left side), it is assume that a light emission point 7 is present within the stack 3 which is associated with light emission. Of light beams emitted from the light emission point 7 in all directions, when light beams removed by the influence of absorption and total reflection are excluded, there remain the following two light beams, that is, a light which is emitted from the light emission point 7 and exits as such toward the glass substrate 1 (transparent substrate) disposed on the side of the first transparent electrode 2 as one of the pair of electrodes, and a light which is emitted from the light emission point 7, travels toward the sealing layer 6 disposed on the side of the second transparent electrode 4 as the other of the pair of electrodes and is reflected by the surface of the sealing layer 6 to travel toward the glass substrate 1.

When the two light beams are present in the structure of the conventional image display device, the light beams interfere with each other at an interface 8 between the stack 3 associated with light emission and the first transparent electrode 2 or the like.

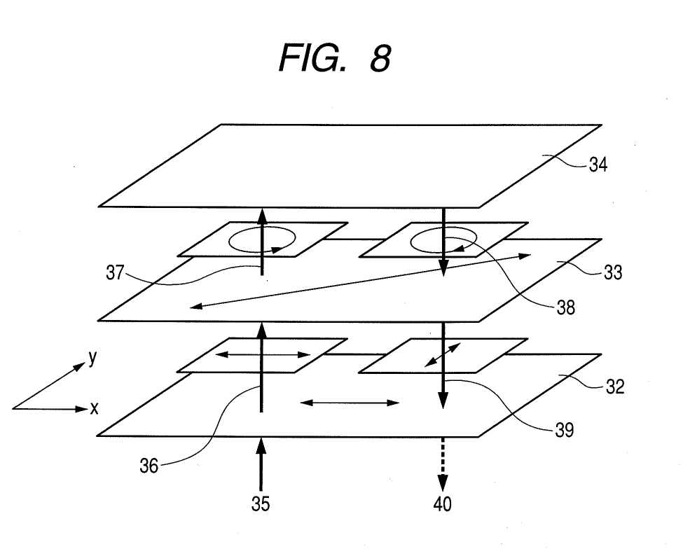

However, in the light emitting apparatus according to this embodiment, the circularly polarizing filter 5 is disposed between the light emission point 7 and the sealing layer 6 serving as the reflective layer. Therefore, the light traveling from the light emission point 7 to the sealing layer 6 side (that is, the optical filter and reflective layer side) is reflected by the surface of the sealing layer 6 through the function of the circularly polarizing filter 5 and the sealing layer 6. Then, the reflected light is removed at a point at which the light exits from the circularly polarizing filter 5 (a point indicated by reference numeral 9 in FIG. 1). This behavior is the same as that of ambient light illustrated in FIG. 8. That is, because the light traveling from the light emission point 7 to the side of the sealing layer 6 serving as the reflective layer does not return to the interference point 8, an interference phenomenon with the light traveling from the light emission point 7 directly to the glass substrate 1 side is not caused.

Here, since the emission layer isotropically emits light, it is considered that the light traveling from the light emission point 7 toward the sealing layer 6 serving as the reflective layer and the light traveling from the light emission point 7 directly toward the glass substrate 1 are approximately equal in amount. When only the light traveling from the light emission point 7 toward the sealing layer 6 serving as the reflective layer is removed as described in this embodiment, the amount of removed light is 50%. This is identical to the case where the amount of light traveling to the outside is reduced by a circularly polarizing filter by 50% in the conventional example in which the circularly polarizing filter is disposed on a surface of a glass substrate.

However, according to this embodiment, because significant variation in extraction efficiency due to a film thickness error can be eliminated, the ease of producing the image display devices can be improved.

Next, the behavior of ambient light is described with reference to FIG. 1 (right side). As illustrated in FIG. 1, most of light from the outside is incident on the circularly polarizing filter 5 through the glass substrate 1, the first transparent electrode 2, the stack 3 associated with light emission, and the second transparent electrode 4. The incident light is reflected by the sealing layer 6 serving as the reflective layer and enters the circularly polarizing filter 5 again. At this time, the circularly polarizing filter 5 and the sealing layer 6 serving as the reflective layer function as described with reference to FIG. 8. Therefore, the ambient light is removed at a point at which the light exits from the circularly polarizing filter 5 (point indicated by reference numeral 10), so that the light is not radiated through the glass substrate 1 to the outside again.

As described above, even when the circularly polarizing filter 5 is disposed between the light emission point 7 and the sealing layer 6 serving as the reflective layer, ambient light can be removed as with the conventional image display device.

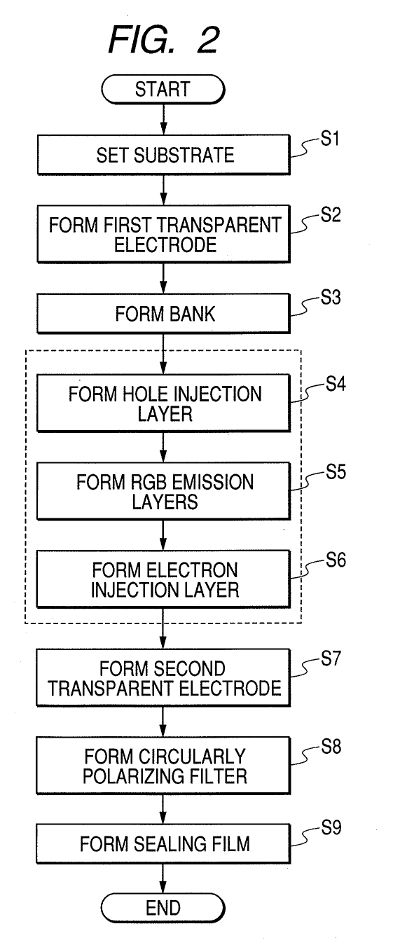

Next, a procedure for producing an image display device used for a display apparatus according to an embodiment of the present invention is described with reference to FIG. 2. FIG. 2 is a flow chart illustrating the procedure for producing the image display device used for the display apparatus according to the embodiment of the present invention.

As illustrated in FIG. 2, in order to produce the image display device used for the display apparatus according to the embodiment of the present invention, a glass substrate serving as a transparent substrate 1 is set in a production apparatus and wiring or the like is formed depending on a driving method (Step S1). To be specific, in the case of the active matrix drive, TFTs for switching and for drive current flow, and data storage capacitors are formed.

In Step S2, a first transparent electrode of ITO or the like is formed corresponding to the disposition of the display pixels on the glass substrate processed depending on the driving method, by steps including sputtering vapor deposition and photolithography.

Then, layers of a stack associated with light emission are formed sequentially. Here, when a low molecular organic EL material is used, the stack is formed by vapor deposition. This method is featured by that the film thickness can be easily controlled, while it is difficult to produce a large-screen display apparatus. Further, when a middle molecular or high molecular organic EL material is used, the stack can be formed by coating, so that a large-screen display apparatus can be produced. In this embodiment, a method of forming the stack by coating is described.

There are several types of methods of forming a stack by coating. For example, there is an ink-jet system in which a pressure is applied to a nozzle by use of a piezoelectric element or the like to eject an organic material dissolved in a solvent to a substrate. There is also a nozzle system in which grooves (banks) are formed on a substrate and an organic material dissolved in a solvent is poured in between grooves (banks) by using a thin nozzle. Moreover, there is also a spray CVD system in which an organic material dissolved in a solvent is atomized and sprayed to a substrate. Further, there is also an electrostatic spray deposition (ESD) system in which an organic material dissolved in a solvent is forcibly sprayed to a substrate with a voltage being applied between a nozzle and the substrate. In this embodiment, the stack is formed using the nozzle system. However, it is needless to say that the other systems can also be applied to the present invention.

In Step S3 following Step S2 described above, banks necessary to apply an organic material dissolved in a solvent are formed on the substrate. As a material of the banks, polyimide or the like can be used. Polyimide is dissolved in a solvent and applied entirely to the substrate by a spin coating method or the like, and the banks are formed corresponding to display pixels by a photolithography step. After that, baking is performed to cure the banks.

The stack associated with light emission is formed as follows.

In the process for forming the stack associated with light emission, a hole injection layer is first formed above the substrate (Step S4). To be specific, when PEDOT-PSS is used for the hole injection layer, an aqueous solution of PEDOT-PSS is poured in between the banks by the nozzle system to form the hole injection layer. After that, baking is performed to evaporate the residual solvent.

Then, in Step S5, organic EL materials corresponding to three primary colors of R, G, and B are each dissolved in an organic solvent such as toluene and poured on the hole injection layer between the banks by separate nozzles to form the emission layer. The conventional image display device utilizes the interference effect, so that there are different film thicknesses suitable for the respective colors. Therefore, it is very difficult to obtain a uniform film thickness entirely on the surface of a large-area substrate. In contrast to this, in this embodiment, the light interference effect is small, so that the demand for film thickness is reduced.

Then, in Step S6, an electron injection layer is formed. To be specific, the electron injection layer made of Cs₂CO₃ is formed on the emission layer by vacuum vapor deposition or the like.

Then, in Step S7, an ITO film is formed as the second transparent electrode through sputtering vapor deposition or the like.

Then, in Step S8, a circularly polarizing filter is formed. The circularly polarizing filter has a film shape and is formed so as to cover the substrate entirely.

Finally, in Step S9, sealing treatment is performed. At this time, a sealing film may be formed by CVD. Alternatively, in Step S7, a sealing film may be formed on a rear surface of a film-shaped circularly polarizing filter beforehand and the second transparent electrode is covered with the circularly polarizing filter with the sealing film. That is, the circularly polarizing filter and the reflective layer may each be formed in a film shape and one surface of the image display device may be covered therewith to seal the image display device.

By performing the above steps, the image display device used for the display apparatus according to the embodiment of the present invention is produced. Incidentally, in the step of forming the stack associated with light emission, an electron blocking layer and a hole blocking layer for adjusting the carrier distribution may be formed. In addition, a layer for transporting holes to the emission layer may be formed by the nozzle system. Further, when each of the layers is to be formed, a photo-curable material may be used to prevent a material of each layer from being dissolved in a solvent applied thereon.

Next, other embodiments of the display apparatus according to the present invention are described.

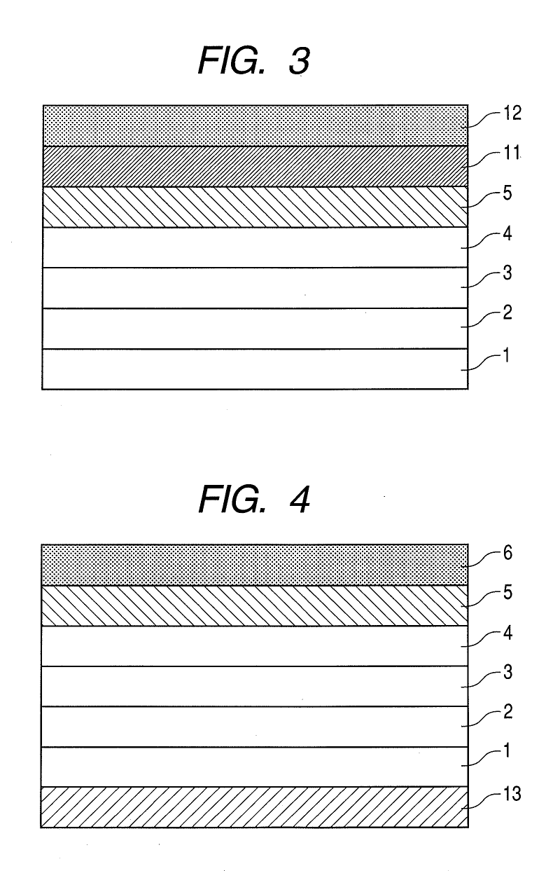

FIGS. 3 and 4 are schematic diagrams each illustrating a structure of an image display device used for a display apparatus according to another embodiment of the present invention. Incidentally, portions having the same functions as those shown in FIG. 1 are identified by like reference numerals and detailed description thereof is omitted.

The image display device illustrated in FIG. 3 has a structure in which a reflective layer 11 is intentionally formed between the circularly polarizing filter 5 and a sealing layer 12, and the sealing layer 12 is formed thereon. By adopting such a structure, a part of light can be prevented from transmitting through the sealing layer 12 serving as the reflective layer to become stray light, thereby preventing the light from adversely affecting image display devices of other colors, TFTs or the like.

The image display device illustrated in FIG. 4 has a structure in which, in order to eliminate the influence of ambient light reflected on a surface of the glass substrate 1, an ambient light diffusion reflection layer 13 is formed under the glass substrate 1. By adopting such a structure, reflection of an image of a person viewing the display apparatus or room light can be removed.

Next, a display apparatus using the image display device described above is described.

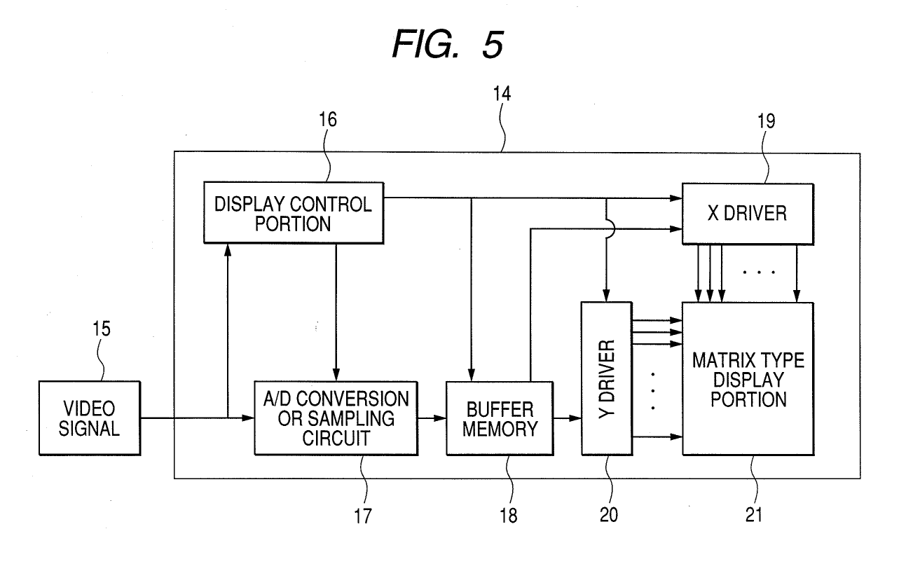

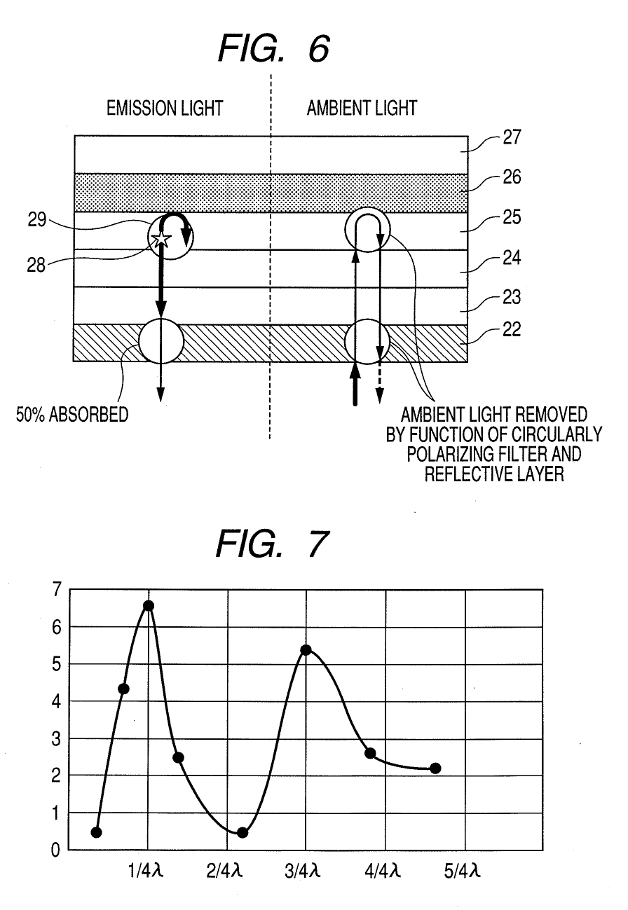

FIG. 5 is a block diagram illustrating the display apparatus according to the embodiment of the present invention.

A display apparatus 14 according to the embodiment of the present invention is constituted using the image display device described above. As illustrated in FIG. 5, the display apparatus 14 includes at least a display control portion 16, an A/D conversion or sampling circuit 17, a buffer memory 18, an X-driver 19, a Y-driver 20, and a matrix display portion 21.

The display control portion 16 controls a series of operations for converting a video signal 15 input from the outside into digital data for respective pixels and displaying the digital data on the matrix display portion 21.

The video signal 15 input to the display apparatus 14 may be either an analog signal such as a video signal or a digital signal such as a DVD signal. When the video signal 15 is input to the display apparatus 14, the video signal is converted into display data for respective pixels in the A/D conversion or sampling circuit 17 under the control of the display control portion 16. Then, the display data for respective pixels is stored in the buffer memory 18.

On the other hand, the display data for respective pixels which is stored in the buffer memory 18 is read out under the control of the display control portion 16. The display data is written in the image display devices corresponding to the display portion 21 by means of the X-driver 19 and the Y-driver 20 to thereby display an image.

The display portion 21 is constituted of the image display devices arranged in a matrix pattern. The drive system for image display devices is broadly divided into a passive matrix drive system and an active matrix drive system.

The passive matrix drive system has a simple structure in which a voltage is applied between one of signal electrodes and one of scanning electrodes which are arranged in rows and columns to allow a pixel interposed therebetween and located at an intersection thereof to emit light. The passive matrix drive system is mainly employed for small-screen organic EL displays. On the other hand, the active matrix drive system requires several thin film transistors (TFTs) and a data storage capacitor, for each pixel. However, the active matrix drive system has a higher response speed than the passive matrix drive system. Further, when the display screen size is large, the active matrix drive system is superior in drive voltage and energy consumption. Therefore, the active matrix drive system is mainly employed for large-screen organic EL displays.

In this embodiment, description has been made by taking as an example a large-screen organic EL display using an active matrix drive system. However, the present invention can be applied even in the case of passive matrix drive used for small-screen displays.

As described above, the display apparatus according to the present invention is configured to include the plurality of image display devices in each of which the circularly polarizing filter is disposed between the light emission point of the stack associated with light emission and the sealing layer serving as the reflective layer. By employing such a configuration, even when the film thickness varies at the time of producing the image display devices, a variation in the amount of extracted light can be suppressed.

Further, according to the conventional technique for disposing the light absorbing layer outside the transparent electrode opposed to the light extraction electrode, light cannot be absorbed and interferes with light on the light extraction side. In contrast to this, according to the display apparatus in the present invention, the light absorptivity can be increased.

According to the conventional technique for disposing the layer for preventing reflection by interference, a stringent requirement is imposed on the precision of the layer structure as is the case with the interference between light traveling to the side opposite to the electrode side and light traveling to the electrode side. In contrast to this, the display apparatus of the present invention is advantageous because the requirement for the precision of the layer structure is relieved.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2007-221980, filed Aug. 29, 2007, which is hereby incorporated by reference herein in its entirety.

1. A display apparatus which comprises a plurality of image display devices each comprising:
a stack which is associated with light emission and comprises a plurality of layers;
a pair of transparent electrodes disposed sandwiching the stack; and
an optical filter having a function of a circularly polarizing filter and a reflective layer that are formed on a side of one of the transparent electrodes which is opposite to the stack side, in the mentioned order from the one transparent electrode side,
wherein the optical filter is formed continuously extending over the plurality of image display devices.

2. The display apparatus according to claim 1, wherein the optical filter removes reflected light resulting from incident ambient light, and also removes light incident on the optical filter and the reflective layer, of light emitted from the stack which is associated with light emission and comprises the plurality of layers.

3. The display apparatus according to claim 1, wherein the optical filter and the reflective layer are each formed in a film shape and cover one surface of the image display device to seal the image display device.

4. The display apparatus according to claim 1, further comprising a transparent substrate disposed on a side of the other of the transparent electrodes which is opposite to the stack side, and an ambient light diffusion reflection layer disposed on a side of the transparent substrate which is opposite to the stack side.

5. The display apparatus according to claim 1, wherein at least one of the plurality of layers of the stack associated with light emission comprises an organic EL material.
